(19) United States
(12) Patent Application Publication
(10) Pub. No.: US 2012/0234242 A1
(43) Pub. Date: Sep. 20, 2012

(54) THERMAL REACTORS WITH IMPROVED GAS FLOW CHARACTERISTICS

(75) Inventor: Robert Jeffrey Bailey, Scotts Valley, CA (US)

(73) Assignee: SoloPower, Inc., San Jose, CA (US)

(21) Appl. No.: 13/100,094

(22) Filed: May 3, 2011

Related U.S. Application Data
(60) Provisional application No. 61/453,413, filed on Mar. 16, 2011.

(51) Int. Cl. H01L 31/18; C23C 16/458; C23C 16/455

(52) U.S. Cl. 118/724

(57) ABSTRACT

The present invention provides methods and systems of reacting a precursor material disposed on a continuous flexible workpiece to form a solar cell absorber. The reactor is configured to have a uniform transition in cross-sectional area from a gas inlet into a reaction space and then a uniform transition in cross-sectional area from the reaction area to a gas outlet. The uniform transition reduces gas turbulence. The continuous flexible workpiece may also be positioned on a floor that is configured to reduce turbulence adjacent the lateral edges of the continuous flexible workpiece.

### CROSS-REFERENCE TO RELATED APPLICATIONS

This application claims the benefit of U.S. Provisional Application No. 61/453,413 filed on Mar. 16, 2011, which is hereby incorporated by reference in its entirety herein.

### BACKGROUND

1. Field of the Invention

The present invention relates to thermal reactors, and more specifically to thermal reactors for preparing thin films of Group IBIIIAVIA compound semiconductors for photovoltaic devices.

2. Description of the Related Art

Solar cells are photovoltaic (PV) devices that convert sunlight directly into electrical energy. Solar cells can be based on crystalline silicon or thin films of various semiconductor materials that are usually deposited on low-cost substrates, such as glass, plastic, or stainless steel.

Thin film based photovoltaic cells, such as amorphous silicon, cadmium telluride, copper indium diselenide or copper indium gallium diselenide based solar cells, offer improved cost advantages by employing deposition techniques widely used in the thin film industry. Group IBIIIAVIA compound photovoltaic cells, including copper indium gallium diselenide (CIGS) based solar cells, have demonstrated the greatest potential for high performance, high efficiency, and low cost thin film PV products.

As illustrated in FIG. 1, a conventional Group IBIIIAVIA compound solar cell 10 can be built on a substrate 11 that can be a sheet of glass, a sheet of metal, an insulating foil or web, or a conductive foil or web. A contact layer 12 such as a molybdenum (Mo) film is deposited on the substrate as the back electrode of the solar cell. An absorber thin film 14 including a material in the family of Cu(In,Ga)(S,Se)₂ is formed on the conductive Mo film. The substrate 11 and the contact layer 12 form a base layer 13. Although there are other methods, Cu(In,Ga)(S,Se)₂ type compound thin films are typically formed by a two-step process where the components (components being Cu, In, Ga, Se and S) of the Cu(In,Ga)(S,Se)₂ material are first deposited onto the substrate or a contact layer formed on the substrate as an absorber precursor, and are then reacted with S and/or Se in a high temperature annealing process.

After the absorber film 14 is formed, a transparent layer 15, for example, a CdS film, a ZnO film or a CdS/ZnO film-stack, is formed on the absorber film 14. Light enters the solar cell 10 through the transparent layer 15 in the direction of the arrows 16. The preferred electrical type of the absorber film is p-type, and the preferred electrical type of the transparent layer is n-type. However, an n-type absorber and a p-type window layer can also be formed. The above described conventional device structure is called a substrate-type structure. In the substrate-type structure light enters the device from the transparent layer side as shown in FIG. 1. A so called superstrate-type structure can also be formed by depositing a transparent conductive layer on a transparent superstrate, such as glass or transparent polymeric foil, and then depositing the Cu(In,Ga)(S,Se)₂ absorber film, and finally forming an ohmic contact to the device by a conductive layer. In the superstrate-type structure light enters the device from the transparent superstrate side.

Contrary to CIGS and amorphous silicon cells, which are fabricated on conductive substrates such as aluminum or stainless steel foils, standard silicon solar cells are not deposited or formed on a protective sheet. Such solar cells are separately manufactured, and the manufactured solar cells are electrically interconnected by a stringing or shingling process to form solar cell circuits. In the stringing or shingling process, the (+) terminal of one cell is typically electrically connected to the (−) terminal of the adjacent solar cell. Circuits may then be packaged in protective packages to form modules. Each module typically includes a plurality of strings of solar cells which are electrically connected to one another.

In a thin film solar cell employing a Group IBIIIAVIA compound absorber, the cell efficiency is a strong function of the molar ratio of IB/IIIA. If there are more than one Group IIIA materials in the composition, the relative amounts or molar ratios of these IIIA elements also affect the properties. For a Cu(In,Ga)(S,Se)₂ absorber layer, for example, the efficiency of the device is a function of the molar ratio of Cu/(In+Ga). Furthermore, some of the important parameters of the cell, such as its open circuit voltage, short circuit current and fill factor, vary with the molar ratio of the IIIA elements, i.e. the Ga/(Ga+In) molar ratio. In general, for good device performance the Cu/(In+Ga) molar ratio is kept at around or below 1.0. On the other hand, as the Ga/(Ga+In) molar ratio increases, the optical bandgap of the absorber layer increases and therefore the open circuit voltage of the solar cell increases while the short circuit current may typically decrease. It is important for a thin film deposition process to have the capability of controlling both the molar ratio of IB/IIIA, and the molar ratios of the Group IIIA components in the composition.

As mentioned above, the second step or the reaction step of the two-step process involves the reaction process of the precursor stack that is formed at the first step of the two step process. The reaction process can be performed in radiation heating reactors or thermal reactors using, for example, resistance heaters. In general the thermal reactors can be atmospheric-pressure (AP) or Sub-Atmospheric (SA) thermal reactors. Such reactors are generally designed for thermal processing of thin-film solar cell materials. Although in the prior art the reactors have been described in some detail there is very little description of the design details essential to provide good uniformity of the final product. This uniformity is typically but not limited to deposited film thickness uniformity in a CVD or similar reactor, or uniformity of composition in a selenization reactor for formation of CuInGaSe (CIGS) layers or similar materials. Described reactor features are mainly limited to the general reactor configuration, including locations of heating zones, gas inlets and outlets, and reaction zones, and overall operation modes. Missing from many of these descriptions are details concerning optimum or desired configuration of the wetted internal surfaces of the reactor that are exposed to the process gases and constrain and direct the process gases over the substrate during the reaction process.

Internal design of the reactors is critical for the quality of the manufactured thin films. Deposition and growth of layers forming a thin film solar cell in a roll-to-roll or in-line process is attractive for higher throughput, lower cost and better yield of such approaches. There is still a need to develop roll-to-roll or in-line growth CIGS growth techniques where the CIGS material compositions are tightly controlled.

### SUMMARY OF THE INVENTION

The present invention provides a thermal reactor and reaction method for forming thin films from precursor materials deposited on substrates.

An aspect of the present invention includes a thermal reactor applying a process gas more uniformly along the length of a workpiece including a precursor material layer during its transit through an internal volume of the thermal reactor.

Another aspect of the present invention includes a roll-to-roll thermal reactor applying a process gas more uniformly along the length of a flexible continuous workpiece including a precursor material layer during its transit through an internal volume of the roll-to-roll thermal reactor.

The aforementioned needs are satisfied in one embodiment by a reactor for reacting a precursor material disposed on a top surface of a continuous workpiece to form a solar cell absorber. In this embodiment, the reactor comprises an elongated chamber to flow at least one process gas flow and to advance the continuous workpiece in a process direction between an entrance opening located at a first end of the elongated chamber and an exit opening located at a second end of the elongated chamber. In this embodiment, the elongated chamber includes at least one delivery region including the entrance opening of the elongated chamber, the delivery region having an inner peripheral surface defining an inner space having a length extending along the process direction and a cross-sectional area, wherein the process gas flow is introduced into the delivery region thought a gas inlet located adjacent the entrance opening. In this embodiment, the elongated chamber also includes a reaction region including the exit opening of the elongated chamber, the reaction region being heated to react the precursor, the reaction region having an inner peripheral surface defining an inner space having a length extending along the process direction and a cross sectional area, wherein the cross-sectional area of the reaction region is greater than the cross-sectional area of the delivery region, wherein the process gas flow flows through the reaction region towards an exhaust opening located adjacent the exit opening. In this embodiment, the elongated chamber also includes at least one gas expansion region that connects the delivery region and the reaction region, the gas expansion region having an inner peripheral surface defining an inner space having a length extending along the process direction and a cross-sectional area that uniformly increases along the process direction toward the reaction region, wherein the gas expansion is configured to uniformly heat and expand the process gas flow before entering the reaction region within its uniformly expanding inner space.

In another embodiment, the aforementioned needs are satisfied by a reactor for reacting a precursor material disposed on a top surface of a continuous workpiece to form a solar cell absorber. In this embodiment, the reactor comprises a reaction chamber having an inlet and an outlet and defining an inner space having a length extending along the process direction and a cross-sectional area. In this embodiment, the reactor further includes at least one gas expansion chamber having an inlet and an outlet wherein the outlet of the gas expansion chamber is coupled to the inlet of the reaction chamber and wherein the continuous workpiece travels through the gas expansion chamber into the reaction chamber. In this embodiment, the reactor further includes a gas supply system that supplies process gas into the inlet of the at least one gas expansion chamber at a first temperature. In this embodiment, the reactor further includes a heating system that heats gas within the reaction chamber to a second temperature so as to react the precursor material formed on top of the continuous workpiece to form a solar absorber and so that gas that is in the gas expansion chamber heats from the first temperature to the second temperature which results in expansion of the gas in the gas expansion chamber as the gas travels in the process direction, wherein the cross-sectional area of the gas expansion region is dimensioned to increase in the process direction in a first proportional relationship to the expansion of the gas in the process direction so as to reduce turbulence of the gas in the gas expansion chamber.

These and other objects and advantages will become more apparent from the following description taken in conjunction with the accompanying drawings.

### BRIEF DESCRIPTION OF THE DRAWINGS

FIG. 1 is a schematic side view of a thin film solar cell including a Group IBIIIAIVA compound absorber layer;

FIG. 2A is schematic view of an embodiment of a roll-to-roll reactor of the present invention;

FIG. 2B is a schematic view of another embodiment of the roll-to-roll reactor of the present invention;

FIG. 2C is a graph showing a thermal profile of the reactors shown in FIGS. 2A and 2B;

FIG. 2D is a schematic view of a test reactor that does not include a gas expansion section;

FIG. 3A is a schematic partial cut away view of a portion of the reactor shown in FIG. 2A;

FIG. 3B is a schematic cross sectional view of an elongated chamber of the reactor shown in FIG. 2A;

FIGS. 4A-4B are schematic cross-sectional views of the elongated chamber including co-translating floor pieces adjacent the workpiece;

FIG. 5 is a schematic cross-sectional view of the elongated chamber including another co-translating floor piece embodiment adjacent the workpiece;

FIG. 6 is a schematic side view of a portion of a roll-to-roll system including a roll-to-roll co-translating floor piece application mechanism;

FIG. 7 is a schematic side view of a reactor applying non-contact heating to a workpiece;

FIG. 8 is a schematic side view of a reactor applying partial-contact heating to a workpiece;

FIG. 9A is a schematic cross-sectional view of the reactor shown in FIG. 7 with floor pieces; and

FIG. 9B is a schematic cross-sectional view of the reactor shown in FIG. 8 with floor pieces.

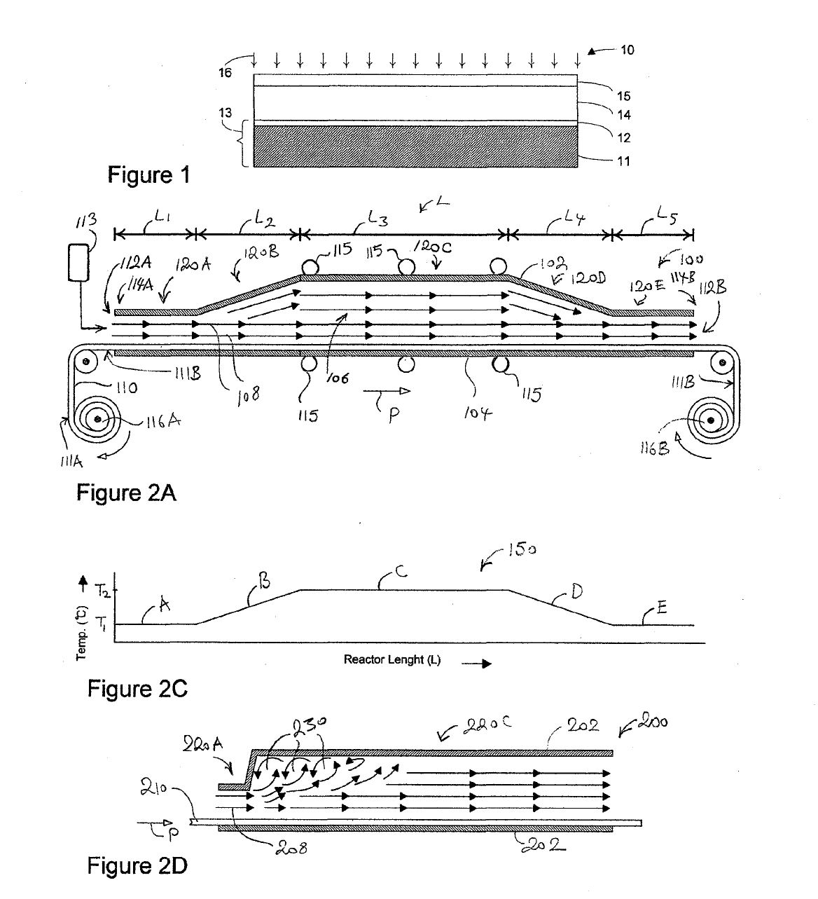

### DETAILED DESCRIPTION

The present invention provides a method and apparatus to react precursor films to form thin films. In one embodiment, a multilayer Group IBIIIAVIA precursor deposited on continuous substrate is thermally reacted to manufacture a Group IBIIIAVIA solar cell absorber. A CIGS precursor comprising Cu, In, Ga and at least one Group VIA material such as Se may be reacted in a roll-to-roll process reactor that applies a process temperature to the precursor layer at a predetermined rate to convert the CIGS precursor into a CIGS thin film absorber layer. The process involves heating the CIGS precursor to a reaction temperature range of 300-700° C., preferably to a range of 400-600° C., in the presence of at least one of a reactive gas containing selenium (Se) and an inert gas such as nitrogen (N₂), while the CIGS precursor on the continuous substrate is advanced through the roll-to-roll process reactor.

It has been observed that a roll-to-roll or continuous-process reactor used for thermal processing, thin-film reaction, or thin-film deposition should provide as uniform a processing environment as possible along the length of the reactor in the direction of substrate travel (the “axial” direction) as well as in the perpendicular (“transverse”) direction. For wide substrates, especially for thin-film solar cell applications, transverse process uniformity is very important and often hard to achieve. Although the uniformity of substrate heating is important, it is not a sufficient condition for acceptable reactor performance. It has been further observed that features employed for good heating uniformity, for example non-contact substrate heating zones where substrates are heated via thermal radiation, may have superior thermal performance at the cost of degraded gas flow characteristics in some applications, which can negate the effects of the improved thermal uniformity. Additionally, for many applications involving reactive substrates where uniformity of the thermal and ambient gas during substrate heating or cooling is important, the changes in reactor temperature in the heating and/or cooling zones affect gas flow uniformity which disturbs the axial and transverse gas flow uniformity, detrimentally affecting the uniformity of the reacted film. Even the very act of translating a substrate through a stationary enclosure of the reactor causes gas flow variations at the edge of the substrate. Reactors employing a moving substrate in an otherwise stationary reactor employing flowing reacting or inert gases may have several inherent sources of gas flow non-uniformity. These factors are addressed by the various embodiments disclosed below and the described reactor embodiments reduce these sources of non-uniformity.

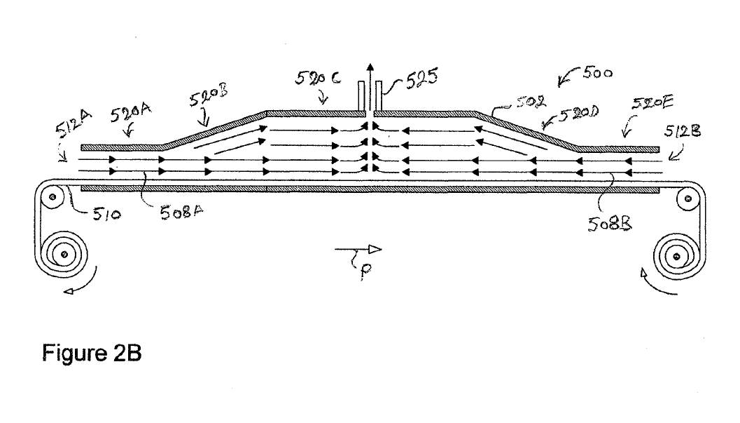

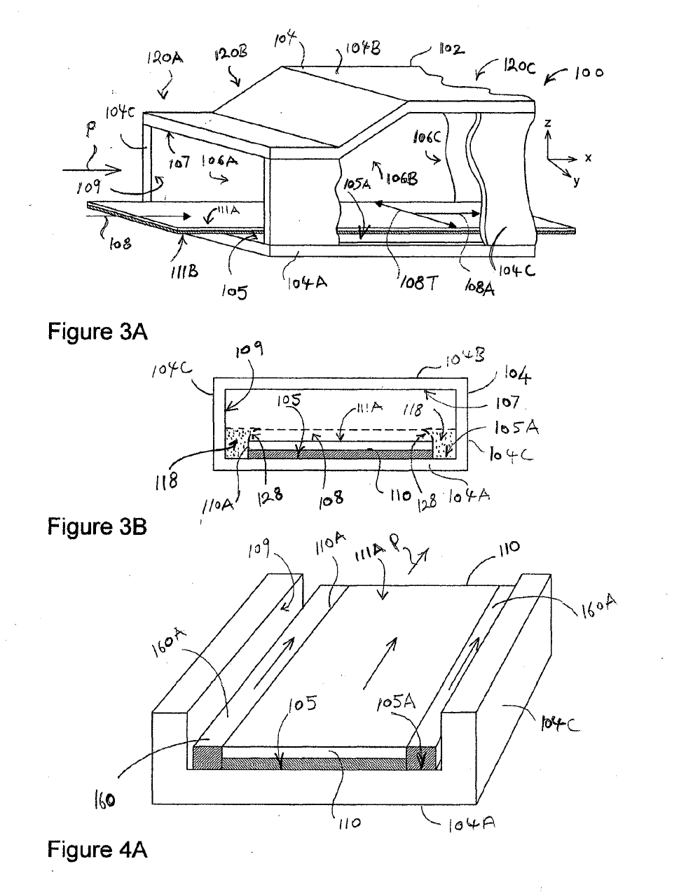

FIG. 2A shows, in a schematic side view, an embodiment of a continuous thermal process reactor 100 or roll-to-roll thermal process reactor of the present invention, which will be referred to as the reactor 100 hereinafter. The reactor 100 includes an elongated chamber 102 or a reactor chamber having a peripheral wall 104 defining an internal process space 106 or process space to flow a process gas flow, denoted by arrows 108. The reactor 100 also advances a continuous workpiece 110 in a process direction ‘P’ between an entrance opening 112A located at a first end 114A of the elongated chamber 102 and an exit opening 112B located at a second end 114B of the elongated chamber 102. The process direction is parallel to the axial direction of the elongated chamber and the process space 106. In this embodiment an axial length ‘L’ of the elongated chamber is greater than the width “W’ (see FIG. 3A) or transverse length of the elongated chamber 102. The axial length is shown as a line denoted ‘L’ above the reactor 100 in FIG. 2A. In a roll-to-roll process operation, the continuous workpiece 110 may be a sheet-shaped workpiece or web that is unwound from a supply spool 116A adjacent the first end 114A as a fresh or un-processed workpiece, advanced through the process space 106 and picked up and wound around a receiving spool 116B adjacent the second end 114B as a reacted or processed workpiece. In this embodiment, a top surface 111A of the continuous workpiece 110 is exposed to the process space 106 through which the workpiece is advanced while a back surface 111B is supported by a bottom wall 104A of the peripheral wall 104. Although not shown in FIG. 2A, a supply container holding the supply spool 116A and a receiving container holding the receiving spool 116B may be sealably connected to the entrance opening 112A and the exit opening 112B respectively. Such supply and receiving containers are described in the pending U.S. Application filed on Nov. 12, 2007 with Ser. No. 11/938,679, entitled Reel-to-Reel Reaction of Precursor Film to Form Solar Cell Absorber, which is also assigned to the assignee of the present invention and which is incorporated herein by reference. The top surface 111A includes a precursor layer to be processed or reacted and the back surface 111B is the back surface of a continuous substrate such as a stainless steel foil or another conductive foil such as aluminum foil. A moving mechanism (not shown) tensions, advances, and supports the workpiece 110 as the workpiece is advanced through the elongated chamber 102. As shown in FIG. 2A, the process gas including at least one of a reactive gas such as a selenium-containing gas and an inert gas such as nitrogen may be delivered into the process space 106 from a gas supply system 113 through the entrance opening 112A or a gas inlet (not shown) adjacent to the entrance opening in the process direction ‘P’ and an exhaust gas that is produced during the reaction is removed through the exit opening 112B or a gas exhaust adjacent (not shown) to the exit opening 112B.

The elongated chamber 102 includes a delivery section 120A, which is kept at a low T₁ temperature, to introduce the process gas over the advancing workpiece; a gas expansion section 120B to allow the process gas to uniformly expand with reduced turbulence; a reaction section 120C that is heated by heating members to the reaction temperature T₂ to react the precursor as the workpiece advances through the reaction section; a gas contraction section 120D that allows the process gas to cool more uniformly with reduced turbulence; and an exit section 120E from which the substrate exits. The gas expansion and gas contraction sections 120B and 120D are transition regions in which the process gas 108 is expanded and contracted respectively. In the embodiment shown in FIG. 2A, process gases are exhausted through the exit opening 112B located at the exit section 120E. The length ‘L₃’ of the reaction section 120C is typically greater than the length ‘L₂’ and ‘L₄’ of the gas expansion and contraction sections 120B and 120D and the length ‘L₁’ and ‘L₅’ of the delivery and exit sections 120A and 120E. The length ‘L₃’ of the reaction section 120C can range from 1 to 50 m with a typical value near 8 m. Depending on the width of the workpiece, the inner width of the elongated chamber may be in the range of 0.1 to 2 meters, preferably slightly greater than 1 meter for a workpiece with 1 meter width.

The expansion and contraction sections 120B and 120D can range from 100 to 3000 mm in length, with a typical length near 300 mm. The height of the delivery and exit sections 120A and 120E range from 1 to 25 mm with typical values near 5 mm. These are less than the height of the reaction section 120C, which can range from 10 to 100 mm, but is about 15 mm in one typical embodiment. The height of the gas expansion section 120B preferably increases between the delivery and reaction sections substantially proportional to the absolute change in temperature, whereas the height of the gas contraction region 120D decreases from the reaction section to exit section, preferably in a symmetrical manner. The ratio of the heights in the reaction section 120C to the delivery or exit sections can range from 2:1 to 4:1, depending on the temperature in the reaction region, with a typical value of 3:1 for a process near 500° C. In the embodiment depicted in FIG. 2A, the widths of all five sections may be the same. In this configuration, the gas flow expands as it flows between the low temperature delivery section and the heated reaction section, and contracts as it passes to the low temperature exit section. The axial temperature gradient in this region can range from 0.1 to 10° C./mm, with a typical value near 1° C./mm. Uniformly enlarging or decreasing space in the gas expansion and contraction sections 120B and 120D compensates uniform gas volume changes as the gas flow moves toward or away from the reaction section 120C.

The axial and transverse uniformity of the gas flow 108, i.e. a gas flow with reduced unwanted gas turbulence, within the process space 106 may be greatly improved by tailoring the internal volume of the elongated chamber 102 at any axial position to an internal temperature profile that includes a gradual temperature shift between low and high temperatures of the environment such as the one exemplified as a graph 150 in FIG. 2C. A second segment ‘B’ of the graph 150 shown in FIG. 2C shows a gradual temperature change between the low temperature segment ‘A’ and the high temperature segment ‘C’. Similarly, a fourth and fifth segments ‘D’ and ‘E’ show temperature changes in the sections 120D and 120E respectively. In the elongated chamber 102, the gradual temperature change depicted by the segment B is configured to occur in the expansion section 120B so that the resulting gas flow expansion is advantageously compensated with the gradually expanding volume or space of the expansion section 120B. This, in turn, improves the axial and transverse uniformity of the gas flow 108, i.e. a gas flow with reduced unwanted gas turbulence, entering the reaction section 120C from the expansion section 120B and entirely throughout the reaction section 120C. Further, when the elongated chamber's internal volume is scaled with the reactor temperature according to the principles of this embodiment, the axial gas velocity is held essentially constant through changing reactor temperatures between about 0.01 to 0.1 m/s, and typically about 0.02 m/s. This design feature avoids both gas disturbances caused by increasing gas volumes in isothermal regions and increasing gas temperatures in constant-volume regions. Because the gas expands in direct proportion to the available volume, and vice versa, changes in gas velocity and direction are reduced in regions with varying temperatures, ensuring a much more constant axial gas flow velocity and reducing transverse flow disturbances. Similarly, the gradual temperature reduction depicted by the segment D in the graph 150 is configured to occur in the contraction section 120D so that as the resulting gas flow contraction is advantageously compensated with the gradually reduced volume or space of the contraction section 120D.

From the foregoing, it will be apparent that there is a desire to be able to control the volume of the expansion section 120B and contraction section 120D so that the heating and cooling gas flows through these regions with reduced turbulence. As discussed above, the reactant gas is supplied to the inlet via a gas supply system 113 at room temperature. There are heating elements 115 adjacent the reaction section 120C and potentially the expansion section 120B and the contraction section 120D. The reactant gas is thus heated from around room temperature in the inlet section 120A to a process temperature that can be approximately 500° C. By maintaining a ratio of the cross-sectional area of the expansion section 120B to the temperature of the gas during the expansion section of approximately 300 mm along the length of the expansion section 120B, the amount of turbulence in the reactant gas in the expansion section 120B can be maintained at a sufficiently low amount so that a desired uniformity of reaction in the reaction section 120C can be maintained.

Similarly, in the contraction section 120D, the reactant gas is being cooled from approximately 500° C. to room temperature at the outlet section 120E. This can also result in turbulence that can affect the uniformity of the resultant material. To reduce this turbulence, the ratio of the cross-sectional area of the contraction section 120D to the gas temperature is maintained at approximately 0.1 cm²/K along the length of the contraction section 120D.

In another embodiment shown in FIG. 2B, a reactor 500 may have an elongated chamber 502 including both delivery and exit sections 520A and 520E having the entry and exit openings 512A and 512B respectively for the entry and exit of a workpiece as in the manner described in the previous embodiment. In this embodiment, the process gas is delivered through both ends of the elongated chamber 502. Accordingly, a first process gas flow 508A is delivered into the elongated chamber through the entrance opening 512A or a gas inlet adjacent the entrance opening, and a second gas flow 508B is delivered trough the exit opening 512B or a gas inlet adjacent the exit opening. The gas flows 508A and 508B may or may not be delivered with the same flow rate and extracted through an internal exhaust port 525 connected to the reaction section 520C. This configuration and gas delivery from opposing directions may be desirable due to the need to contain process gases within the interior of the elongated chamber. The reactor may contain one or more separate gas exhaust ports depending on the desired configuration. In this embodiment, there are two gas expansion sections, namely a first gas expansion section 520B to expand the first gas flow 508A and a second gas expansion section 520D to expand the second gas flow 508B. Since both gas flows move from low to high temperature, the same principles for the expansion section apply: the internal volume expands proportionally to the increasing temperature of the inlet gas to reduce gas flow non-uniformity. Thus, in both gas expansion sections, the internal volume expands proportionally to the increasing temperature of the inlet gas to reduce the gas flow non-uniformity. Dimensions of both expansions zones 520B and 520D are typically similar to that described above and shown in FIG. 2A. The composition of the gases in the reactor may range from purely inert gases in the terminal sections (e.g., Ar, N₂) to entirely reactive gases in the reaction section (e.g. O₂ for an oxidation process) and all fractions in between. In one embodiment typically used for selenization of CIGS absorber layers, the gas composition in the reaction section are approximately 5% Se vapor by volume. The graph 150 shown in FIG. 2C is also applicable to the reactor 500 shown in FIG. 2B.

FIG. 2D shows the load end of an exemplary reactor 200 having an elongated chamber 202 without a gas expansion section shown in the above embodiments for comparison reasons. The elongated chamber 202 is composed of a low temperature inlet section 220A to introduce a process gas flow 208 and a continuous workpiece 210, and a high temperature reaction section 220C where the reaction process takes place. As shown, as the gas flow 208 enters into the heated reaction section 220C from the inlet section 220A, the abrupt increase in volume and temperature results in the formation of gas recirculation cells 230 near the point of entry, which disturbs the gas flow uniformity and hence the reaction process. Further, as the gas flow 208 continues to be heated within the reaction section 220C the gas recirculation cells 230 are gradually suppressed within the reaction section. Both factors can affect the reactor gas flow uniformity. As seen in FIG. 2D, as opposed to the gradual temperature change and volume expansion in the gas expansion section 120B shown in FIG. 2A and in the gas expansion sections 520A and 520D shown in FIG. 2B, the temperature change and the volume change occur non-simultaneously in the elongated chamber 202. Unlike the uniform gas flow provided with the expansion sections shown in FIGS. 2A and 2B, both factors involving the gas recirculation cells within the elongated chamber 202 induce changes in the axial and transverse gas flow uniformity.

FIG. 3A shows a partial cutaway view of the load end of an exemplary embodiment of the elongated chamber 102 shown in FIG. 2A. As seen, the peripheral wall 104 of the elongated chamber 102 includes the back wall 104A, the top wall 104B and the side walls 104C, all made of heat conducting material. The internal space 106 of the elongated chamber may be further defined by an inner surface 105 of the bottom wall 104A or the inner bottom surface 105, an inner surface 107 of the top wall 104B or the inner top surface 107, and inner surfaces 109 of the side walls 104C or the inner side wall surface 109. The internal space 106 may be divided into a delivery space 106A defined by the corresponding inner surface portions shaping the delivery section 120A; an expansion space 106B defined by the corresponding inner surface portions shaping the gas expansion section 120B; and a reaction space 106C defined by the corresponding inner surface portions shaping the reaction section 120C of the elongated chamber 102. Accordingly, the axis of the elongated chamber 102 and the inner space 106 defined by the inner surfaces is preferably parallel to the x-axis; the transverse axis is parallel to the y-axis; and the vertical axis is parallel to the z-axis.

As is understood, the cross sections of the delivery and the reaction spaces 106A and 106C may not change along the length of the delivery and the reaction sections 120A and 120C while the cross section of the gas expansion space 106B uniformly increases towards the reaction section 120C in accordance with the increasing temperature in the expansion space. In this embodiment, the delivery section 120A may be maintained at the T₁ by cooling the delivery section using a cooling system (not shown), and the reaction section may be maintained at the T₂ temperature by a heating system (not shown). T₁ temperature is in the range of 10-50° C., preferably 20-30° C. and the T₂ temperature is in the range of 250-700° C., preferably 450-600° C. for CIGS film reaction. The back surface 111B of the continuous workpiece 110, which includes the continuous conductive substrate, may be supported by the inner bottom surface 105 as the workpiece 110 is advanced through the elongated chamber 102. The inner surface 105 and the sheet-shaped workpiece are in parallel alignment. The process gas flow 108 flows over the CIGS precursor at the top surface 111A. The gas flow 108 has an axial flow component 108A or axial gas flow 108A and a transverse gas flow component 108T or transverse flow 108T. As is understood the axial gas flow 108A is parallel to the axis of the inner space 106 and extends along the process direction ‘P’. The transverse gas flow 108T is parallel to the transverse axis of the inner space 106.

During a reaction process, for wide workpieces such as workpieces with continuous substrates having a width of about a meter or more, transverse uniformity is very important within the reaction section 120C. Although the uniformity of heating is very important for uniformly heating the workpiece, the uniformity of the process gas flow by uniformly distributing the axial and transverse gas flows is also important and affects the uniformity of the finished product. As will be exemplified below, the translation of a workpiece through a stationary reaction enclosure may cause unwanted gas flow variations at the edge of the workpiece.

FIG. 3B shows an exemplary cross-sectional view of the reaction section 120C as the workpiece 110 is moved during the process with the gas flow 108 extended over the top surface 111A of the workpiece. The process gas flow 108, however, may further extend over the exposed surfaces 105A of the inner bottom surface by the transverse flow 108T and forms process gas films 118 on the exposed surfaces 105A by filling the gap between the side walls 104C and the edges 110A of the workpiece. This is an undesirable situation. As the workpiece is moved, the process gas flow 108 flowing in the direction of the process ‘P’ and the process gas films 118 on both exposed surfaces 105A form shear boundaries 128 along the edges 105A of the workpiece due to the finite viscosity of the process gas flow 108 and the gas films 118. The shear boundaries 128 establish gas transition zones extending over the edges 110A of the workpiece 110. The gas transition zones affect the transverse gas flow 108T at the edges 110A and degrade process uniformity near the edges 110A, and thereby degrading the uniformity of the forming CIGS layer. As will be described more fully below, a solution to this problem may be moving the shear boundary 128 and hence the associated gas transition zone further away from the edges 110A using an auxiliary floor 160. The auxiliary floor 160 may also be referred to as floor, floor piece, false floor, edge extender, false edge or edge sheet. The auxiliary floor 160 may co-translate alongside the edges of the workpiece or may be stationary and attached to the interior of the elongated chamber. Preferably, the stationary auxiliary floor may be positioned co-planar and adjacent the edged of a workpiece or a portion of the workpiece that is not supported by a bottom wall, i.e. suspended within a reactor chamber.

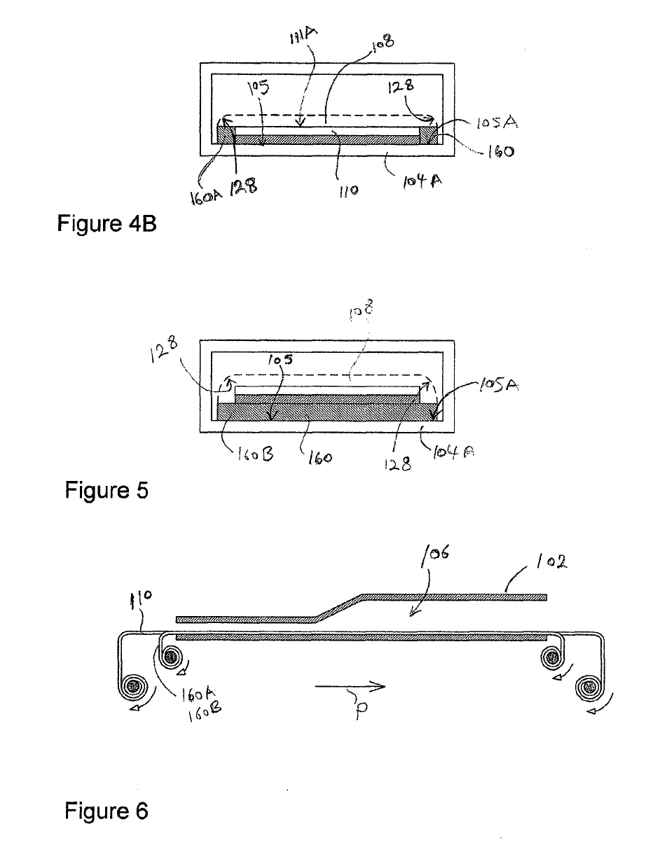

As shown in FIGS. 4A-4B, in one embodiment, floor pieces 160A are positioned over the exposed surfaces 105A and co-translated alongside the edges 110A of the workpiece to move the shear boundary 128 away from the edges 110A and towards the side walls 104C. The floor pieces 160A are belts made of flexible materials such as metallic materials or flexible polymeric materials that can be use for high temperature applications The transverse gas flow 108T continues over the floor pieces 160A moving with the same velocity as the workpiece in the process direction ‘P’, thereby moving the shear boundary away and reducing its effect along the edges 110A of the workpiece. As shown in FIG. 5, in another embodiment, a floor sheet 160B may function in the same manner and co-translate with the workpiece at the same velocity. The floor sheet 160B may support the workpiece 110 while covering the exposed surfaces 105A of the inner bottom floor 105. The floor sheet 160B may be made of a heat conducting sheet material such as a metallic foil.

As shown in FIG. 6 using a partial side view of the elongated chamber 102, in one embodiment, the floor pieces 160A or floor sheet 160B may be supplied using a roll-to-roll mechanism alongside the workpiece 110. A circulating endless loop made of the floor pieces 160A or the floor sheet 160B may also be used in this embodiment.

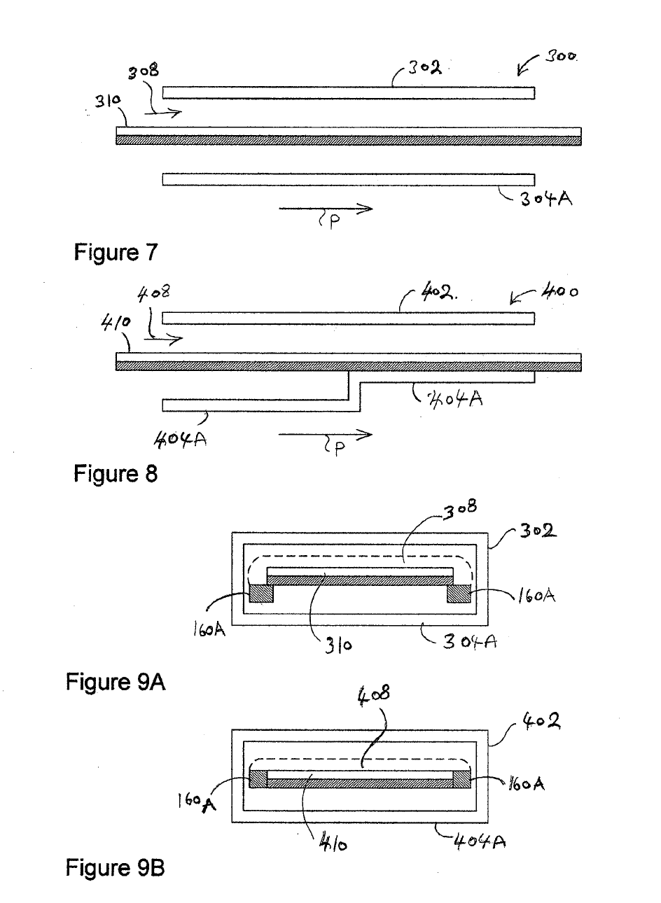

In another embodiment, the floor pieces 160A may also be used in a non-contact thermal reactor 300 including a reactor housing 302 and a partial contact thermal reactor 400 including a reactor housing 402 shown in FIGS. 7 and 8 respectively. As shown in FIG. 7, the workpiece 310 has no contact with a bottom wall 304A as it travels through the housing 302 while exposed to a process gas flow 308. However, as shown in FIG. 8, the workpiece 410 touches a step at a bottom wall 404A as it travels through the housing 402 while exposed to a process gas flow 408. Such elevations in bottom wall profile can act like barriers and cause unwanted process gas flow disturbances. FIGS. 9A and 9B show, in front cross sectional views, exemplary floor pieces engaged to the workpieces 310 and 410 shown in the reactors shown in FIGS. 7 and 8 respectively. In this embodiment, the floor pieces 160A may be co-translating, i.e., moving, as in the previous embodiment, or stationary and they may also be placed in a manner to support the edges of the workpiece. The use of a stationary or moving co-planar floor pieces adjacent to the workpiece edges is found to essentially decouple the gas volumes above and below the substrate, greatly unifying the gas flow patterns within the process space of the reactors. Such floor pieces may also effectively prevent the process gas flow disturbances caused by abrupt changes in bottom wall elevation as shown in FIG. 8. In one embodiment, the moving floor pieces may be supplied roll-to roll or re-circulating loop as described above, or may be part of a single recirculating marginal loop used in the rest of the reactor. If the floor pieces are stationary, a stationary plate or plates obstructing gas flow between the upper and lower regions may be fixed to the reactor side walls and adjacent to the moving workpiece. Referring to FIG. 9A, in an example, the floor pieces 160A are engaged to the workpiece 310, which is suspended in the reactor housing 302 in an encroaching or supporting manner. Referring to FIG. 9B, in another example, the floor pieces 160A are placed adjacent to the edges of the workpiece 410, which is partially suspended in the reactor housing 402. In both examples, the floor pieces 160A may be stationary or moving.

Although the present invention is described with respect to certain preferred embodiments, modifications thereto will be apparent to those skilled in the art. Thus the scope of the present invention should not be limited to the foregoing discussion but should be defined by the appended claims.

What is claimed is:

1. A reactor for reacting a precursor material disposed on a top surface of a continuous workpiece to form a solar cell absorber, the reactor comprising:
an elongated chamber to flow at least one process gas flow and to advance the continuous workpiece in a process direction between an entrance opening located at a first end of the elongated chamber and an exit opening of the elongated chamber, the elongated chamber including:
at least one delivery region including the entrance opening of the elongated chamber, the delivery region having an inner peripheral surface defining an inner space having a length extending along the process direction and a cross-sectional area, wherein the process gas flow is introduced into the delivery region via a gas supply system located adjacent the entrance opening;
a reaction region including the exit opening of the elongated chamber, the reaction region being heated to react the precursor, the reaction region having an inner peripheral surface defining an inner space having a length extending along the process direction and a cross sectional area, wherein the cross-sectional area of the reaction region is greater than the cross-sectional area of the delivery region, wherein the process gas flow flows through the reaction region towards an exhaust opening located adjacent the exit opening; and
at least one gas expansion region that connects the delivery region and the reaction region, the gas expansion region having an inner peripheral surface defining an inner space having a length extending along the process direction and a cross-sectional area that uniformly increases along the process direction toward the reaction region, wherein the gas expansion is configured to uniformly heat and expand the process gas flow before entering the reaction region within its uniformly expanding inner space.

2. The reactor of claim 1, further comprising an auxiliary floor that is positioned in the elongated chamber with the continuous workpiece wherein the auxiliary floor is positioned adjacent the lateral edges of the continuous workpiece to reduce turbulence in the gas flow adjacent the lateral edges.

3. The reactor of claim 2, wherein the auxiliary floor is co-translating with the workpiece.

4. The reactor of claim 2, wherein the floor is fixedly mounted in the elongated chamber.

5. The reactor of claim 1, wherein the cross-sectional area of the reaction region and the delivery region are constant along the process direction.

6. The reactor of claim 1, further comprising a gas contraction region that is connected to an outlet of the reaction region and an exit region that is connected to the gas contraction region.

7. The reactor of claim 6, wherein the expansion and contraction regions are approximately 100 to 3000 mm in length.

8. The reactor of claim 7, wherein the expansion and contraction regions are approximately 300 mm in length.

9. The reactor of claim 6, wherein the height of the delivery and exit regions range from 1 to 25 mm.

10. The reactor of claim 9, wherein the delivery and exit regions are approximately 5 mm in height.

11. The reactor of claim 6, wherein the reaction region has a height in the range of between approximately 10 to 100 mm.

12. The reactor of claim 11, wherein the reaction region has a height of approximately 15 mm.

13. The reactor of claim 6, wherein the ratio of heights in the reaction region to the delivery or exit chamber is in a range of between 2:1 to 4:1.

14. The reactor of claim 13, wherein the ratio of heights in the reaction region to the delivery region is approximately 3:1 for a reaction region that performs reactions at a temperature of approximately 500° C.

15. The reactor of claim 1, wherein the at least one delivery region comprises a first and second delivery regions and wherein the at least one gas expansion region comprises a first and second gas expansion regions and wherein the reaction region includes an exhaust opening that exhausts the process gas flow.

16. The reactor of claim 15, wherein the first expansion region connects the first delivery region to a first end of the reaction region and the second expansion region connects the second delivery region to a second end of the reaction region.

17. The reactor of claim 15, wherein the at least one process gas flow comprises a first and second process gas flows and wherein the first gas flow is delivered through the first delivery region while the second gas flow is delivered through the second delivery section.

18. The reactor of claim 1, wherein the reaction chamber is a non-contact reaction chamber.

19. The reactor of claim 1, wherein the reaction chamber is a partial contact reaction chamber.

20. The reactor of claim 1, wherein the reactor is a roll-to-roll reactor including a workpiece moving assembly, the workpiece moving assembly unrolls the continuous workpiece from a fresh workpiece roll, advances through the elongated chamber and rerolls as a reacted workpiece roll.

21. A reactor for reacting a precursor material disposed on a top surface of a continuous workpiece to form a solar cell absorber, the reactor comprising:
a reaction chamber having an inlet and an outlet and defining an inner space having a length extending along the process direction and a cross-sectional area;
at least one gas expansion chamber having an inlet and an outlet wherein the outlet of the gas expansion chamber is coupled to the inlet of the reaction chamber and wherein the continuous workpiece travels through the gas expansion chamber into the reaction chamber;
a gas supply system that supplies process gas into the inlet of the at least one gas expansion chamber at a first temperature; and
a heating system that heats gas within the reaction chamber to a second temperature so as to react the precursor material formed on top of the continuous workpiece to form a solar absorber and so that gas that is in the gas expansion chamber heats from the first temperature to the second temperature which results in expansion of the gas in the gas expansion chamber as the gas travels in the process direction, wherein the cross-sectional area of the gas expansion region is dimensioned to increase in the process direction in a first proportional relationship to the expansion of the gas in the process direction so as to reduce turbulence of the gas in the gas expansion chamber.

22. The reactor of claim 21, further comprising a delivery chamber and an exit chamber.

23. The reactor of claim 21, further comprising a gas contraction chamber having an inlet and an outlet wherein the inlet of the gas contraction chamber is connected to the outlet of the reaction chamber and wherein the gas contraction chamber receives the process gas at the second temperature and cools the process gas to a third temperature thereby causing the gas volume to contract and wherein the cross-sectional area of the gas contraction region is dimensioned to decrease in the process direction in a second proportional relationship to the contraction of gas so as to reduce turbulence in the gas contraction chamber.

24. The reactor of claim 21, wherein the first proportional relationship ranges from 0.01 to 1 cm²/K.

25. The reactor of claim 21, wherein the second proportional relationship ranges from 0.01 to 1 cm²/K.

26. The reactor of claim 22, wherein the cross-sectional area of the reaction chamber and the delivery chamber are constant along the process direction.

27. The reactor of claim 21, further comprising a gas contraction chamber that is connected to an outlet of the reaction chamber and an exit chamber that is connected to the gas contraction region.

28. The reactor of claim 27, wherein the expansion and contraction chambers are approximately 100 to 3000 mm in length.

29. The reactor of claim 28, wherein the expansion and contraction chambers are approximately 300 mm in length.

30. The reactor of claim 22, wherein the height of the delivery and exit chambers range from 1 to 25 mm.

31. The reactor of claim 30, wherein the delivery and exit chambers are approximately 5 mm in height.

32. The reactor of claim 22, wherein the reaction chamber has a height in the range of between approximately 10 to 100 mm.

33. The reactor of claim 32, wherein the reaction chamber has a height of approximately 15 mm.

34. The reactor of claim 22, wherein the ratio of heights in the reaction chamber to the delivery or exit chamber is in a range of between 2:1 to 4:1.

35. The reactor of claim 34, wherein the ratio of heights in the reaction chamber to the delivery chamber is approximately 3:1 for a reaction chamber that performs reactions at a temperature of approximately 500° C.

36. The reactor of claim 21, wherein the reaction chamber is a non-contact reaction chamber.

37. The reactor of claim 21, wherein the reaction chamber is a partial contact reaction chamber.

38. The reactor of claim 21, wherein the at least one gas expansion chamber comprises a first and a second gas expansion chamber receive gas from the gas supply systems and provide gas into the reaction chamber from a first and a second process direction.

39. The reactor of claim 38, wherein the first and second process directions are opposed to each other and wherein the reaction chamber includes an exhaust opening.

40. The reactor of claim 21, further comprising an auxiliary floor that is positioned in the reaction chamber with the continuous workpiece wherein the auxiliary floor is positioned adjacent the lateral edges of the continuous workpiece to reduce turbulence in the gas flow adjacent the lateral edges.

41. The reactor of claim 40, wherein the auxiliary floor is co-translating with the workpiece.

42. The reactor of claim 40, wherein the floor is fixedly mounted in the reaction chamber.
